(19) United States
(12) Patent Application Publication
(10) Pub. No.: US 2008/0217740 A1
(43) Pub. Date: Sep. 11, 2008

(54) SEMICONDUCTOR DEVICE AND METHOD OF MANUFACTURING THE SAME

(76) Inventors: Nobuhiro Shiramizu, Musashino (JP); Hiromi Shimamoto, Iruma (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/017,438

(22) Filed: Jan. 22, 2008

(30) Foreign Application Priority Data
Mar. 9, 2007 (JP) 2007-059807

(51) Int. Cl. H01L 27/06; H01L 21/02

(52) U.S. Cl. 257/536; 438/384; 257/E27.024; 257/E21.006

(57) ABSTRACT

An object of the invention is to provide a resistor element whose contact area is self-alignedly formed to reduce the contact area size and contact resistance variation and which can be formed finely and with high precision at low cost. A thin metal film is deposited on a substrate surface covered with an insulation film on which wirings are formed. The thin metal film is anisotropically etched to leave a desired portion such that the desired portion straddles between wirings, self-alignedly connecting the thin metal film to be a resistor and the wirings.

### CLAIM OF PRIORITY

The present application claims priority from Japanese application JP 2007-059807, filed on Mar. 9, 2007, the content of which is hereby incorporated by reference into this application.

### BACKGROUND OF THE INVENTION

1. Field of the Invention

The present invention relates to a semiconductor device having thin metal film resistors and a method of manufacturing the same, and more particularly, to a semiconductor device having thin metal film resistors which, compared with related art thin metal film resistors, can be finely formed to be uniform in resistance at low cost and a method of manufacturing the same.

2. Description of the Related Arts

Compared with single crystal silicon resistors (diffused resistors), polycrystal silicon resistors can be finely formed with ease, their parasitic capacitance is small, and they generate no substrate bias effect. Because grain boundaries are present in polycrystal silicon, however, polycrystal silicon has disadvantages in that its resistance variations and temperature coefficient of resistance (TCR) are larger than those of single crystal silicon. The performance of analog integrated circuits and high-performance digital integrated circuits, in particular, is largely affected by the accuracy of passive elements, and resistance variations with time and variations of properties including TCR have been factors in limiting the performance of such circuits. Thin metal film resistors, on the other hand, feature small TCR values and can be formed on a topmost layer of integrated circuit chips, in addition to also having advantages similar to those of polycrystal silicon resistors. Hence, thin metal film resistors are advantageous in that their resistance values can be easily adjusted (trimmed), for example, using laser and in that their resistance values can be adjusted by mask modification with quick turnaround time (QTAT).

For the reasons described above, resistor elements, other than the single crystal silicon resistors and polycrystal silicon resistors that have been in use, formed of thin resistive metal films, for example, films of chromium silicon (CrSi), nickel chrome (NiCr), tantalum nitride (TaN), and chromium-silicon oxide (CrSiO) have been increasing in application to integrated circuits (see JP Patent No. 2699559, JP-A No. 2005-235888, JP-A No. S61-100956, and JP-A No. S63-184377, for example).

### SUMMARY OF THE INVENTION

The resistivity of such thin metal films is, however, relatively low compared with that of single crystal silicon or polycrystal silicon. To obtain sheet resistance high enough for practical use, therefore, such thin metal films require to be made considerably thin. In the case of tantalum nitride (TaN) films, for example, the film thickness has been required to be 50 nm or less.

Contact holes (electrode extraction portions) to be provided in resistors have been made finer, too, so that selective dry etching technology which makes fine processing easy is generally used to form contact holes. In selective dry etching, however, it is difficult to achieve required etching selectivity between an insulation film and a metal film. Therefore, in cases where a general device structure in which contact holes for electrode extraction are provided directly above a resistor as shown in FIG. 5 (see JP Patent No. 2699559, for example) is used, etching the insulation film over the resistor layer causes the surface of the thin metal film to be reduced. This reduces the thickness of the thin metal film resistor and causes problems of increases in contact resistance and contact resistance variations.

To cope with the situation, a device structure in which, as shown in FIG. 6, contacts between a thin metal film and wiring electrodes are provided on top portions of wirings has been proposed (see JP-A No. 2005-235888, for example). Such a device structure, though it can solve the foregoing problems, makes it difficult to finely form a resistor where the distance between contact holes is short and to achieve high resistance accuracy.

Furthermore, the device structures referred to above require photo-etching to be performed for oxide film patterning and resistor patterning in addition to photo-etching for wiring patterning, so that contact resistance variations increase on account of mask alignment variations between photo-etching processes. This also makes it necessary to secure regions to accommodate mask alignment variations, resulting in reducing layout flexibility.

There have been device structures in which, as shown in FIG. 7, contacts between a thin metal film and wiring electrodes are formed on side portions of wirings (see JP-A No. S61-100956 and JP-A No. S63-184377, for example) In such structures, the widths of the contacts are the same as the width of the thin metal film to be a resistor. Therefore, increasing the wiring film thickness (for example, to 0.4 μm or more) to reduce the parasitic resistance of metal wirings causes, depending on the coverage of the thin metal film, contact area variations and hence contact resistance variations.

Furthermore, depending on the thin metal film material used, there have been problems of changes in thin metal film properties caused when the surface of the thin metal film is oxidized by ozone during ashing performed to remove photoresist.

An object of the present invention is to provide a semiconductor device having high-precision resistors.

Another object of the invention is to provide a semiconductor device having high-precision, fine thin metal film resistors.

Still another object of the invention is to provide a semiconductor device having thin metal film resistors which can be manufactured at low cost.

These and other objects and novel features of the invention will become obvious from the following description and attached drawings.

Of the inventions disclosed in the present application, a representative one will be outlined in the following. The semiconductor device according to the invention has a structure formed as follows: a thin resistive metal film is deposited using sputtering technology on a substrate surface covered with an insulation film on which wirings each having a square or trapezoidal cross-section are formed; a desired portion of the substrate surface is then coated with photoresist such that a pair of wirings to be subsequently made extraction electrodes are straddled by the photoresist; and the substrate surface is then subjected to anisotropic etching. In the structure thus formed, the electrodes of the thin metal film to be a resistor are extracted by the thin metal films formed on side walls of the wirings. This structure solves the above described problems as explained below.

When a thin metal film is deposited on a rough substrate surface by sputtering, thin metal films are also formed self-alignedly on side walls of wirings depending on the coverage characteristic of sputtering. Therefore, etching a thin metal film to which photoresist has been applied such that wirings are straddled by the photoresist makes it possible to form a resistor portion and contact portions of the thin metal film at the same time. Thus, the problem of a contact resistance increase attributable to over-etching of a thin metal film occurring in a related art device structure can be prevented.

Since no area for contact holes and mask alignment is required, resistors can be mounted in a higher density. The absolute value of contact resistance of the contact area between a thin metal film and wiring electrodes and variation of the absolute value can be reduced with the wiring electrodes ranging not only over where they are covered with photoresist but all around the wiring layer.

The processes to be performed to realize the device structure described above are only a sputtering process for depositing a thin metal film and a one-time photo-etching process. Compared with related art device structures, therefore, the device structure of the present invention can be realized in a simpler way by a smaller number of processes at lower cost.

Of the inventions disclosed in the present application, another representative one will be outlined in the following. The semiconductor device according to the invention has a structure formed as follows: first a thin resistive metal film, then a silicon nitride film are deposited using sputtering technology and CVD technology on a substrate surface covered with an insulation film on which wirings each having a square or trapezoidal cross-section are formed; a desired portion of the substrate surface is then coated with photoresist such that a pair of wirings to be subsequently made extraction electrodes are straddled by the photoresist; the silicon nitride film is anisotropically etched and the photoresist is removed; and the thin metal film is anisotropically etched using the silicon nitride that has been anisotropically etched as a mask. In the structure thus formed, the electrodes of the thin metal film to be a resistor are extracted by the thin metal films formed on side walls of the wirings as in the case of the first representative invention described above. This structure, in addition to having the same features as those of the structure according to the first representative invention described above, makes it possible to realize high-precision resistors as explained below.

With the resistivity of a thin metal film being lower than those of single-crystal silicon and polycrystal silicon, the thin metal film is required to be thin to obtain an effective value of sheet resistance. If the surface quality of the thin metal film changes when the thin metal film is subjected to ashing for photoresist removal or heat treatment for wiring formation, electrical properties including sheet resistance of the thin metal film change. In a device structure in which the top surface of each thin metal film resistor is covered with silicon nitride, the above-described changes in the surface quality of the thin metal film can occur only on its side walls. Hence the changes in electrical properties including sheet resistance of the thin metal film can be largely reduced. This makes it possible to realize thin metal film resistors with higher precision than before.

According to this invention, electrodes of thin metal film resistors are self-alignedly extracted, so that it is possible to realize fine, high-precision, high-performance resistor elements allowing high layout flexibility and featuring small parasitic capacitance. Since it is not necessary to form any contact hole for resistor electrode extraction, the device manufacturing process can be more simplified than before to enable cost reduction.

### BRIEF DESCRIPTION OF THE DRAWINGS

FIG. 1A is a cross-sectional side view showing an essential part of an embodiment of a semiconductor device according to the present invention, and FIG. 1B is an enlarged view of a part of FIG. 1A;

FIG. 2 schematically illustrates a planar structure of the semiconductor device shown in FIG. 1A;

FIG. 3A is a cross-sectional side view showing an essential part of another embodiment of a semiconductor device according to the present invention, and FIG. 3B is an enlarged view of a part of FIG. 3A;

FIG. 4 schematically illustrates a planar structure of the semiconductor device shown in FIG. 3A;

FIG. 5 is a cross-sectional side view showing an essential part of a related art thin metal film resistor;

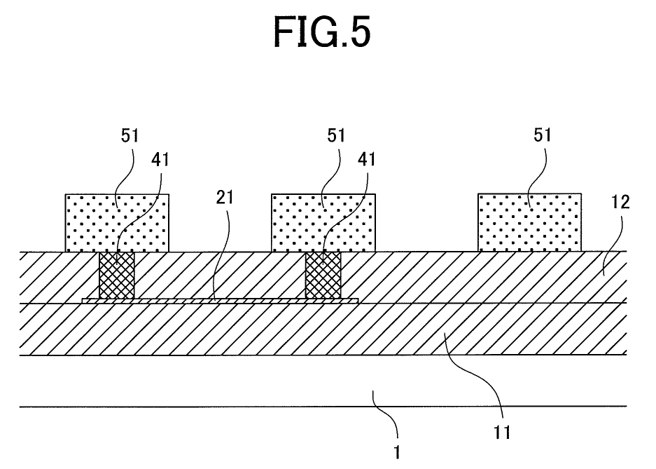

FIG. 6 is a cross-sectional side view showing an essential part of another related art thin metal film resistor;

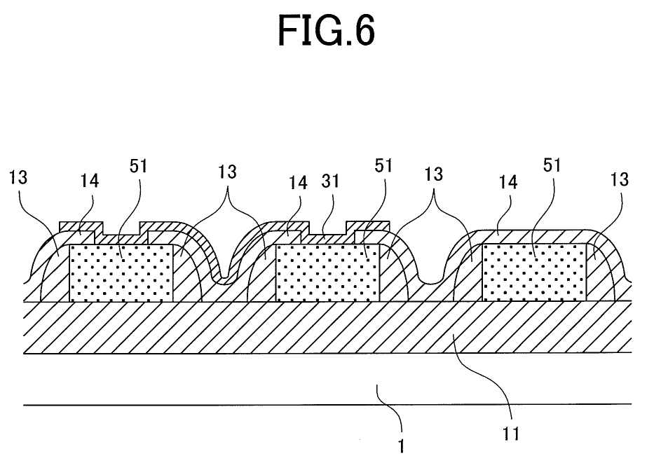

FIG. 7 is a cross-sectional side view showing an essential part of still another related art thin metal film resistor;

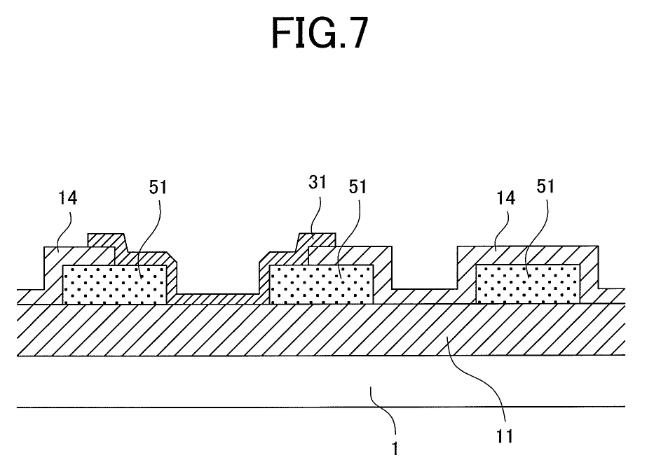

FIGS. 8A to 8D show the manufacturing processes for the semiconductor device shown in FIG. 1A in order, each of FIGS. 8A to 8D being a cross-sectional side view of an essential part of the semiconductor device in a state of being processed in one of the manufacturing processes;

FIGS. 9A to 9E show the manufacturing processes for the semiconductor device shown in FIG. 3A in order, each of FIGS. 9A to 9E being a cross-sectional side view of an essential part of the semiconductor device in a state of being processed in one of the manufacturing processes; and

FIG. 10 shows an example integrated circuit incorporating a semiconductor device according to the present invention.

### DETAILED DESCRIPTION OF THE PREFERRED EMBODIMENTS

Embodiments of the semiconductor device and a method of manufacturing the same according to the present invention will be described in detail below with reference to the attached drawings.

In the attached drawings, essential parts are shown more enlarged than other parts where appropriate to make such essential parts more easily understandable. It goes without saying that the material, conduction type, and conditions of manufacture of each part associated with the invention are not limited to those described for the following embodiments.

### First Embodiment

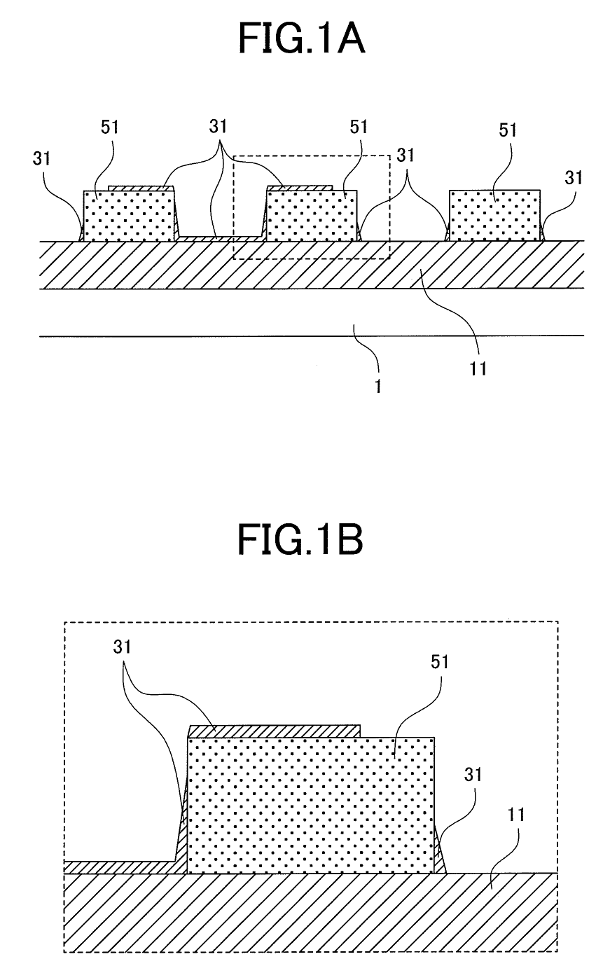

A first embodiment of a semiconductor device according to the present invention will be described below with reference to FIGS. 1A, 1B, 2, and 8A to 8D.

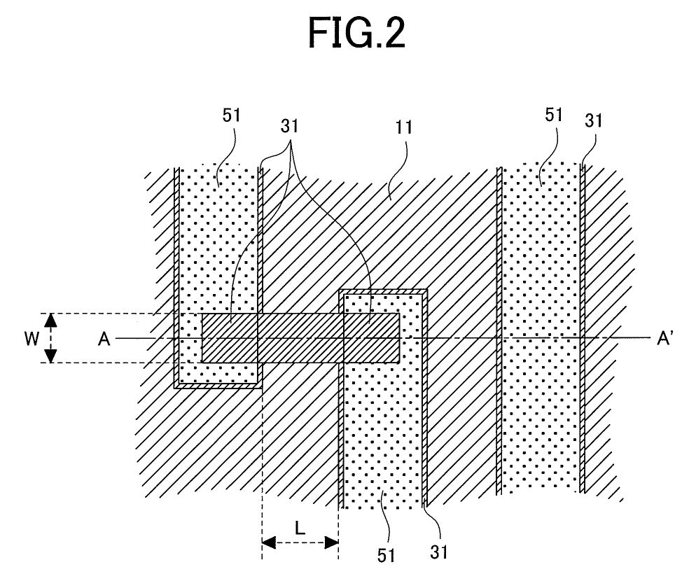

FIG. 2 schematically shows an example planar structure of thin metal film resistor elements according to the invention. As shown, thin metal film resistors are arranged to surround all wiring layers with one resistor element arranged to straddle between two separate wirings.

FIGS. 1A and 1B are cross-sectional views taken along line A-A′ in FIG. 2. All the cross-sectional views referred to in the present application are those taken along the same line. Thin metal films are formed in contact with lower side wall portions (lower peripheral portions) of wirings. Some thin metal film is formed over top portions of two wirings and a desired portion of insulation film in a manner of interconnecting the wirings. Thus, a thin metal film to be a resistor and wirings for electrode extraction are connected self-alignedly, so that it is not necessary to devise a layout which tolerates mask misalignment in photolithography. Furthermore, since no contact resistance variation attributable to uneven dry etching made to form contact holes occurs, resistors can be formed more finely and more precisely than before.

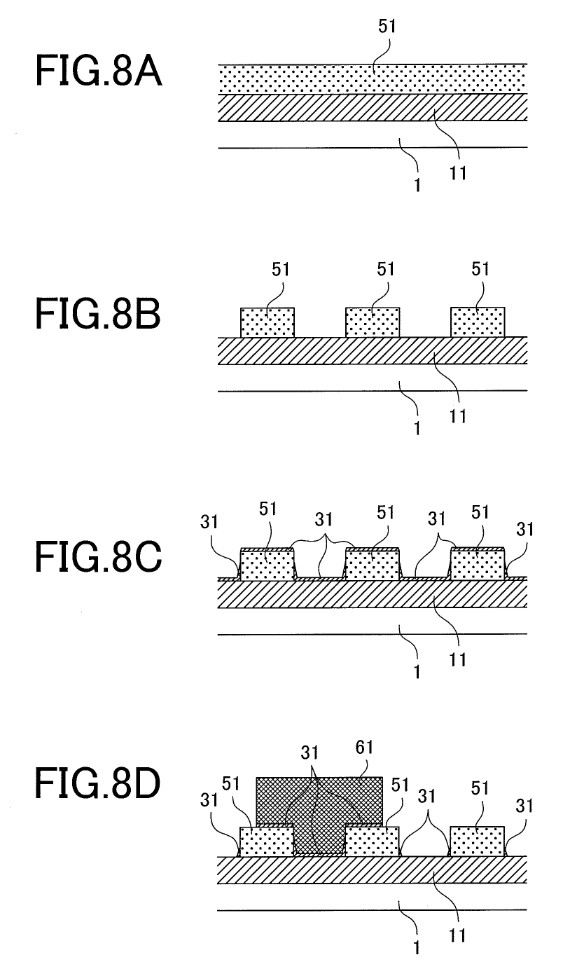

FIGS. 8A to 8D show semiconductor device manufacturing processes according to the present embodiment. The processes shown are performed before the cross-sectional structure shown in FIG. 1A is obtained. The processes will be described below referring to FIGS. 8A to 8D in order.

First, as shown in FIG. 8A, a laminated substrate composed of a silicon substrate 1 coated with silicon dioxide 11 is formed, then an aluminum (Al) film is deposited over the laminated substrate. Next, as shown in FIG. 8B, the aluminum film is patterned into aluminum wirings 51 using known photo-etching technology. Then, as shown in FIG. 8C, a thin metal film 31 of, for example, tantalum nitride (TaN) to be made resistors is deposited over the substrate surface using known sputtering technology. The thin metal film need not necessarily be of tantalum nitride (TaN). It may be a thin resistive metal film of, for example, chromium silicon (CrSi), nickel chrome (NiCr), or chromium-silicon oxide (CrSiO).

When the sputtering process is performed, the thin metal film 31 is also formed on side walls of the aluminum wirings 51 depending on the coverage characteristic of sputtering. Next, as shown in FIG. 8D, photoresist 61 is coated over a desired portion of the substrate surface so that it straddles over a portion of an aluminum electrode, then the thin metal film 31 is anisotropically etched into the desired pattern using known photo-etching technology. In the anisotropic etching, the portion coated with the photoresist 61 of the thin metal film 31 is not etched, so that the portions, left over sidewalls coated with the photoresist 61 of the aluminum wirings, of the thin metal film 31 result in having a higher height from the substrate surface than other portions, left over other sidewalls not coated with the photoresist 61 of the aluminum wirings, of the thin metal film 31. The reason why anisotropic etching is employed in this process is to prevent variations in resistor dimensions and metal wiring deformation which can be caused by over-etching resulting from isotropic etching. Subsequently, removing the photoresist realizes high-precision resistor elements as shown in FIG. 1. This method, compared with related art methods, can realize fine, high-precision resistor elements which can be highly flexibly laid out and whose contact resistance is small with little variation.

The processes to be performed, in addition to a wiring forming process, to realize the device structure described above are only a sputtering process for depositing a thin metal film and a one-time photo-etching process. Thus, compared with a related art device structure, the device structure of the present embodiment can be realized in a simpler way by a smaller number of processes at lower cost.

### Second Embodiment

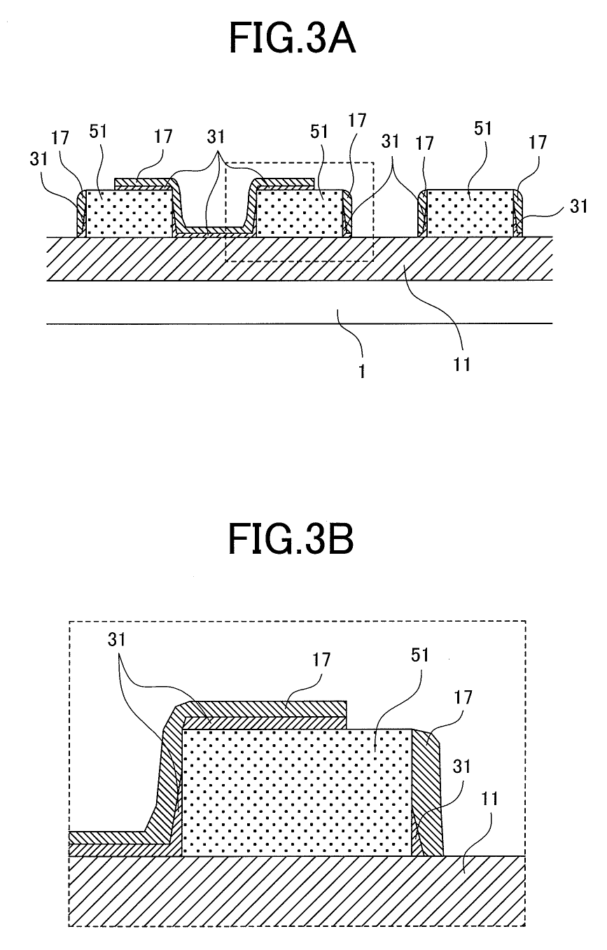

A second embodiment of a semiconductor device according to the present invention will be described below with reference to FIGS. 3A, 3B, 4, and 9A to 9E.

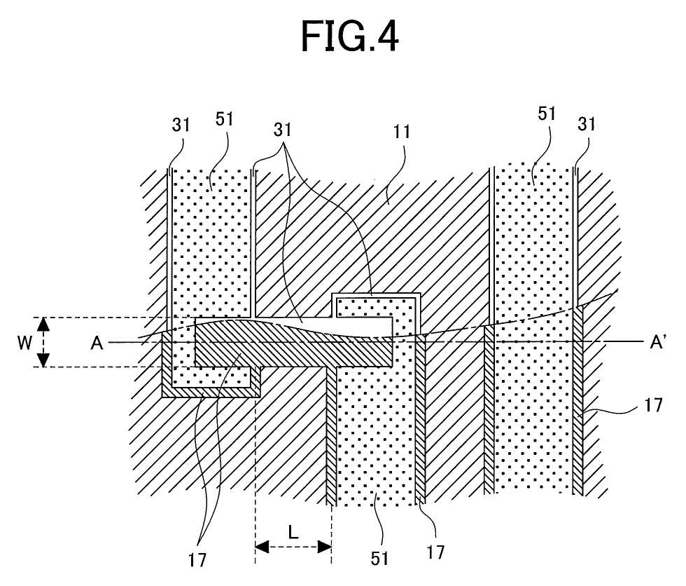

FIG. 4 schematically shows an example planar structure of thin metal film resistor elements according to the present invention. As shown, thin metal film resistors are arranged to surround all wiring layers with one resistor element arranged to straddle between two separate wirings.

FIGS. 3A and 3B are cross-sectional views taken along line A-A′ in FIG. 4. A thin metal film 31 and a silicon nitride film 17 are laminated over a rough substrate surface. The silicon nitride film 17 is used as an etching mask for etching the thin metal film 31 so as to reduce changes in quality of the thin metal film of, for example, tantalum nitride (TaN) caused when the photoresist is removed by ashing. This method, compared with related art methods, makes it possible to more finely form resistors with higher precision.

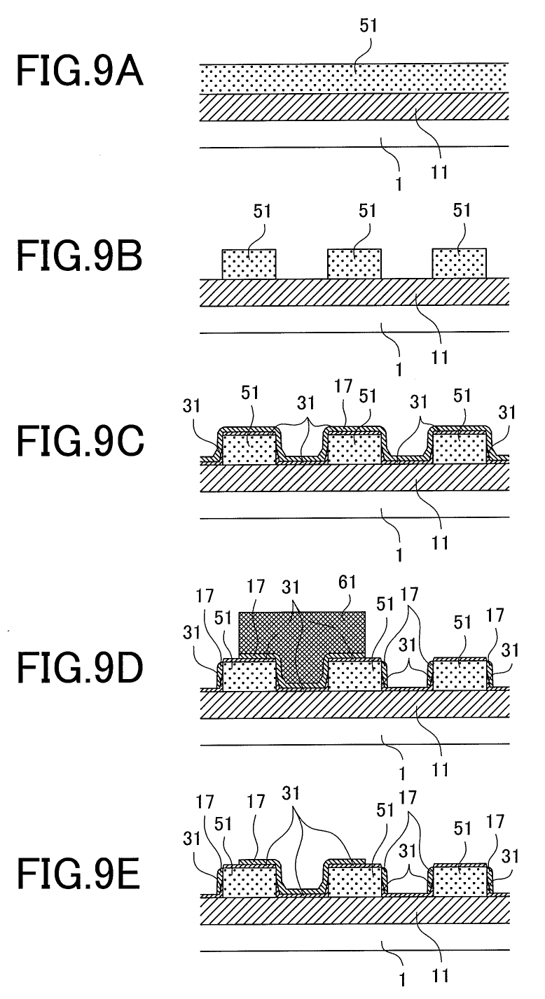

FIGS. 9A to 9E show semiconductor device manufacturing processes according to the present embodiment. The processes shown are performed before the cross-sectional structure shown in FIG. 3A is obtained. The processes will be described below referring to FIGS. 9A to 9E in order.

First, as shown in FIG. 9A, a laminated substrate composed of a silicon substrate 1 coated with silicon dioxide 11 is formed, then an aluminum (Al) film is deposited over the laminated substrate. Next, as shown in FIG. 9B, the aluminum film is patterned into aluminum wirings 51 using known photo-etching technology. Next, as shown in FIG. 9C, a thin metal film 31 to be made resistors is deposited over the substrate surface using known sputtering technology, then a silicon nitride film 17 is deposited over the thin metal film 31 using known CVD technology. Next, as shown in FIG. 9D, photoresist 61 is coated, using known photo-etching technology, over a desired portion of the substrate surface so that it straddles over a portion of an aluminum electrode, then using the photoresist as a mask, the desired portion of the silicon nitride film 17 is anisotropically etched into the desired pattern.

Next, as shown in FIG. 9E, the photoresist 61 is removed by ashing. Subsequently, resistor elements as shown in FIG. 3A can be formed by anisotropically etching desired portions of the thin metal film 31 of, for example, tantalum nitride (TaN) using the silicon nitride film 17 as an etching mask. The anisotropic etching is performed such that portions of the thin metal film 31 are left unetched over lower portions of side walls of the wiring layer and also over a portion of the insulation film surface on which the wiring layer is formed, the portion of the insulation film surface being in contact with the lower portions of side walls of the wiring layer.

The present embodiment has an effect that, because top surface portions of the thin metal film are not exposed to ozone when the photoresist is removed by ashing, property variations caused by oxidation of the thin metal film can be largely reduced Therefore, the semiconductor device structure of the present embodiment makes it possible to largely improve the accuracy of the sheet resistances of thin metal films. Also, for resistor elements including thin metal films left unetched over lower portions of side walls of a wiring layer, contact resistances and contact resistance variations can be reduced.

### Third Embodiment

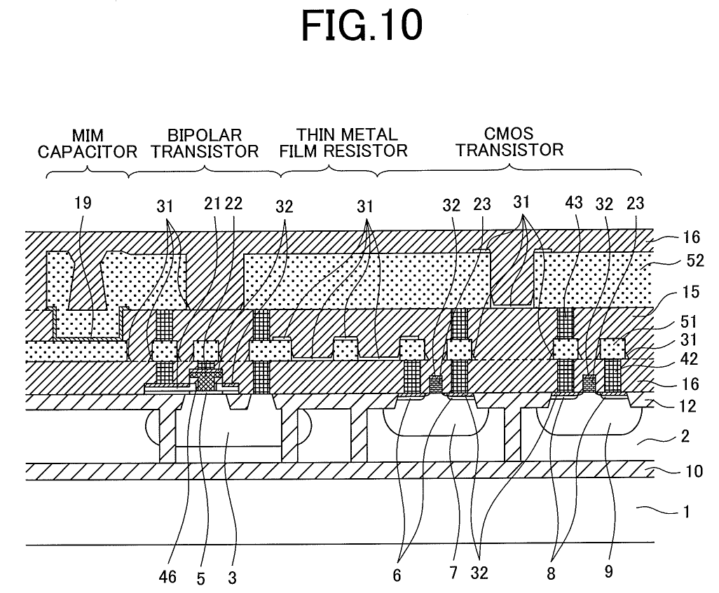

An embodiment of a method of manufacturing a semiconductor device according to the present invention will be described below with reference to FIG. 10. FIG. 10 shows an example of an integrated circuit including thin metal film resistors formed by the semiconductor device manufacturing method according to the present invention. As known from the example shown, the semiconductor device manufacturing method according to the present invention makes it possible to form high-precision resistors by a small number of processes even in cases where thin metal film resistors, bipolar transistors, CMOS transistors, MIM capacitors, and wirings are arranged in high density on a substrate. Furthermore, since a resistor layer can be combined with any wiring layer, it can be formed farther from the substrate than single-crystal silicon resistors and polycrystal silicon resistors. Hence, high-performance resistors with small parasitic capacitance can be easily realized.

As described above, the method of manufacturing a semiconductor device according to the present invention makes it possible to realize integrated circuits incorporating fine, high-precision, high-performance resistors which related art technology has been unable to realize.

The present invention has been concretely described based on the first to third embodiments. The invention, however, is not limited to the embodiments, and it can be modified in various ways without departing from its scope and spirit.

What is claimed is:

1. A semiconductor device, comprising:
a plurality of wiring films selectively provided on a first insulation film provided on a semiconductor substrate; and
a resistor element including a thin metal film which is provided to straddle between a first one of the plurality of wiring films and a second one of the plurality of wiring films and a top surface of which is covered with a second insulation film, the second one of the plurality of wiring films being located to oppose the first one of the plurality of wiring films,
wherein the thin metal film included in the resistor element is in contact with a first conductive layer which includes a thin metal film formed over at least a portion of a sidewall of each of the mutually opposing wiring films, and the thin metal film included in the resistor element includes a second conductive layer including a thin metal film which is formed over a lower side wall portion of each of the mutually opposing wiring films and which is electrically connected with the thin metal film included in the resistor element.

2. A semiconductor device, comprising:
a plurality of wiring films selectively provided on a first insulation film provided on a semiconductor substrate; and
a resistor element including a thin metal film provided to straddle between a first one of the plurality of wiring films and a second one of the plurality of wiring films, the second one of the plurality of wiring films being located to oppose the first one of the plurality of wiring films,
wherein the thin metal film included in the resistor element is in contact with a first conductive layer which includes a thin metal film formed over at least a portion of a sidewall of each of the mutually opposing wiring films, and the thin metal film included in the resistor element includes a second conductive layer including a thin metal film which is formed over a lower side wall portion of each of the mutually opposing wiring films and which is electrically connected with the thin metal film included in the resistor element, and
wherein a vertical height from the semiconductor substrate of the second conductive layer is smaller than a vertical height from the semiconductor substrate of the first conductive layer.

3. A semiconductor device manufacturing method, comprising the steps of:
forming a first insulation film on a semiconductor substrate, then forming a plurality of metal wirings on the first insulation film;
depositing first a thin metal film, then a second insulation film on the semiconductor substrate;
covering a desired portion of the second insulation film with photoresist and anisotropically etching the second insulation film into a pattern using the photoresist as an etching mask;
anisotropically etching the thin metal film into a pattern using the second insulation film, from which the photoresist has been removed, as an etching mask; and
forming the thin metal film on a desired portion of the first insulation film so that the thin metal film straddles between two of the plurality of metal wirings while also leaving the thin metal film over at least a portion of a side wall of each of the two metal wirings.

4. The semiconductor device manufacturing method according to claim 3,
wherein the second insulation film is formed of silicon nitride.

5. The semiconductor device manufacturing method according to claim 3,
wherein the thin metal film is a thin resistive metal film formed of one of chromium silicon (CrSi), nickel chrome (NiCr), tantalum nitride (TaN), and chromium-silicon oxide (CrSiO).

6. The semiconductor device manufacturing method according to claim 4,
wherein the thin metal film is a thin resistive metal film formed of one of chromium silicon (CrSi), nickel chrome (NiCr), tantalum nitride (TaN), and chromium-silicon oxide (CrSiO).
